(19) United States
(12) Patent Application Publication
(10) Pub. No.: US 2008/0121996 A1
(43) Pub. Date: May 29, 2008

(54) Transistor with carbon nanotube channel and method of manufacturing the same

(76) Inventors: Wan-jun Park, Gangnam-gu (KR); Byoung-ho Cheong, Seoul (KR); Eun-ju Bae, Gyeonggi-do (KR); Hans Kosina, Wien (AT); Mahdi Fourfath, Wien (AT)

Correspondence Address: HARNESS, DICKEY & PIERCE, P.L.C., P.O. BOX 8910, RESTON, VA, 20195, US

(21) Appl. No.: 11/224,313

(22) Filed: Sep. 13, 2005

(30) Foreign Application Priority Data
Sep. 13, 2004 (KR) 10-2004-0073082

(51) Int. Cl. H01L 29/78; H01L 21/04

(52) U.S. Cl. 257/365; 438/283; 977/938; 257/E29.264; 257/E21.04

(57) ABSTRACT

A transistor with a carbon nanotube channel and a method of manufacturing the same. At least two gate electrodes are formed on a gate insulating layer formed on a carbon nanotube channel and are insulated from each other. Thus, the minority carrier may be reduced or prevented from flowing into the carbon nanotube channel. Accordingly, it is possible to reduce or prevent a leakage current that is generated when both the majority carrier and the minority carrier flow into the carbon nanotube channel. Therefore, characteristics of the transistor may not be degraded due to the leakage current.

### PRIORITY STATEMENT

This application claims the benefit of Korean Patent Application No. 10-2004-0073082, filed on Sep. 13, 2004, in the Korean Intellectual Property Office, the disclosure of which is incorporated herein in its entirety by reference.

### BACKGROUND OF THE INVENTION

1. Field of the Invention

Example embodiments of the present invention relates to a semiconductor device with a carbon nanotube channel and a method of manufacturing the same, and more particularly, to a transistor with a carbon nanotube channel and a method of manufacturing the same.

2. Description of the Related Art

Carbon nanotubes may have a diameter ten thousand times smaller than the diameter of a human hair, may be stronger than steel, have both semiconductor and metal properties, and/or have better performance than silicon. Also, because carbon nanotubes may have mobility seventy times higher than the mobility of silicon at room temperature, carbon nanotubes may overcome disadvantage of silicon materials, for example, the high noise level of the silicon materials.

Due to one or more of these characteristics, carbon nanotubes may be widely used in semiconductor devices, flat panel displays, batteries, super powerful fibers, biosensors, TV cathode ray tubes (CRTs), etc. Carbon nanotubes may also be used as a nanotweezer, to pinch and release a nano-object.

An example application of carbon nanotubes is a carbon nanotube transistor whose channel is formed of one or more carbon nanotubes.

In a conventional carbon nanotube transistor (hereinafter, referred to as a conventional transistor), a source electrode and a drain electrode may form a Schottky junction together with a carbon nanotube channel.

Therefore, a conventional transistor may be implemented to have one or more of the advantages of carbon nanotubes by forming the channel of a carbon nanotube.

FIG. 1 is a graph illustrating a voltage-current characteristic of a conventional transistor.

In FIG. 1, first and second graphs G1 and G2 represent simulation results at drain voltages of 1.5 V and 0.9 V, respectively. Symbols ∘ and • represent actual test results at the drain voltages of 1.5 V and 0.9 V, respectively. FIG. 1 illustrates that simulation results and actual test results are substantially similar to each other.

FIG. 1 also illustrates that the voltage-current characteristic according to the voltage applied to the drain electrode of the conventional transistor are not different from that of the graph illustrated in FIG. 1.

FIG. 2 is a graph illustrating voltage-current characteristics of a conventional transistor at the drain voltages of 0.3 V and 0.6 V. In FIG. 2, first and second graphs G11 and G22 represent the voltage-current characteristic at the drain voltages of 0.3 V and 0.6 V, respectively.

In both FIGS. 1 and 2, the drain current increases from both sides of a gate voltage at which the drain current is at a minimum.

The drain current at the left side of the gate voltage at which the drain current is a minimum is caused by holes, while the drain current at the right side of the gate voltage is caused by electrons.

In the case of a normal transistor, the drain current of a measurement range is caused by the majority carrier, and the drain current caused by the minority carrier can be ignored because it is much lower than the measurement range. For this reason, in a normal transistor, the drain current does not increase at the gate voltage exceeding the voltage at which the drain current is at a minimum, but has a minimal value.

In the conventional transistors of FIGS. 1 and 2, however, the drain current again increases at the gate voltage exceeding the voltage at which the drain current is at a minimum.

This result indicates the coexistence of the drain currents in the measurement range, which is caused by the holes and electrons. The existence of the drain current caused by the carriers of the opposite polarities within the measurement range means that the current caused by the minority carrier may have a larger value that cannot be neglected. The drain current caused by the minority carrier is a current caused by a carrier, which should not be measured at the gate voltage at which the drain current is at a minimum.

In the conventional transistor, the electrons and the holes flow into the channel as the majority carrier. Therefore, the leakage current may increase and/or the characteristics of the semiconductor device may be degraded.

### SUMMARY OF THE INVENTION

Example embodiments of the present invention provide a transistor with a carbon nanotube channel, which is capable of reducing or preventing a minority carrier from flowing into the carbon nanotube channel.

Example embodiments of the present invention also provide a method of manufacturing the transistor.

In an example embodiment, the present invention is directed to a transistor including a substrate, a first insulating layer formed on the substrate, first and second metal layers formed on the first insulating layer and spaced apart from each other, a nanotube channel formed on the first insulating layer, a second insulating layer covering the nanotube channel, and at least two gate electrodes formed on the second insulating layer, the at least two gate electrodes being electrically insulated from each other.

In another example embodiment, the second insulating layer may be a dielectric layer having a dielectric constant higher than that of the first insulating layer.

In another example embodiment, the at least two gate electrodes may be spaced apart from each other.

In another example embodiment, a third insulating layer is further formed on the second insulating layer to cover the first gate electrode, and the second gate electrode may be formed on the third insulating layer. The first and second gate electrodes may be partially overlapped with each other.

In another example embodiment, a third gate electrode may be further formed on the second insulating layer, the third gate electrode being insulated from the first and second gate electrodes.

In another example embodiment, the present invention is directed to a method of manufacturing a transistor, including forming a first insulating layer on a substrate, forming a nanotube channel on the first insulating layer, forming first and second metal layers on the first insulating layer spaced apart from each other, forming a second insulating layer on the nanotube channel, and forming at least two gate electrodes on a region of the second insulating layer, the at least two gate electrodes being electrically insulated from each other.

In another example embodiment, the at least two gate electrodes may be formed spaced apart from each other by a desired distance.

In another example embodiment, a first gate electrode may be formed on the second insulating layer; a third insulating layer may be formed on the second insulating layer such that the first gate electrode is covered; and a second gate electrode may be formed on the third insulating layer such that the second gate electrode is overlapped with a portion of the first gate electrode.

In another example embodiment, a third (and subsequent) gate electrode may be further formed on the region of the second insulating layer which contacts the nanotube channel, the third gate electrode being insulated from the first and second gate electrodes.

According to example embodiments of the present invention, it is possible to reduce or prevent the minority carrier from flowing into the nanotube channel. Accordingly, it is possible to reduce or prevent the leakage current that is generated when both the majority carrier and the minority carrier flow into the nanotube channel. Therefore, characteristics of the transistor may not be degraded due to the leakage current.

### BRIEF DESCRIPTION OF THE DRAWINGS

The present invention will become more apparent by describing in detail example embodiments thereof with reference to the attached drawings.

FIG. 1 is a graph illustrating simulation and experiment results of a voltage-current characteristic of a conventional carbon nanotube transistor.

FIG. 2 is a graph illustrating a voltage-current characteristic of a conventional carbon nanotube transistor based on the result of FIG. 1.

FIG. 3 is a sectional view of a carbon nanotube transistor according to an example embodiment of the present invention.

FIG. 4 is a sectional view of a carbon nanotube transistor according to another example embodiment of the present invention.

FIG. 5 is a graph illustrating a voltage-current characteristic of the carbon nanotube transistor illustrated in FIGS. 3 and 4.

FIGS. 6 through 9 are example views illustrating sequential procedures of manufacturing the carbon nanotube transistor of FIG. 3.

FIGS. 10 through 12 are example views illustrating sequential procedures of manufacturing a carbon nanotube transistor of FIG. 4.

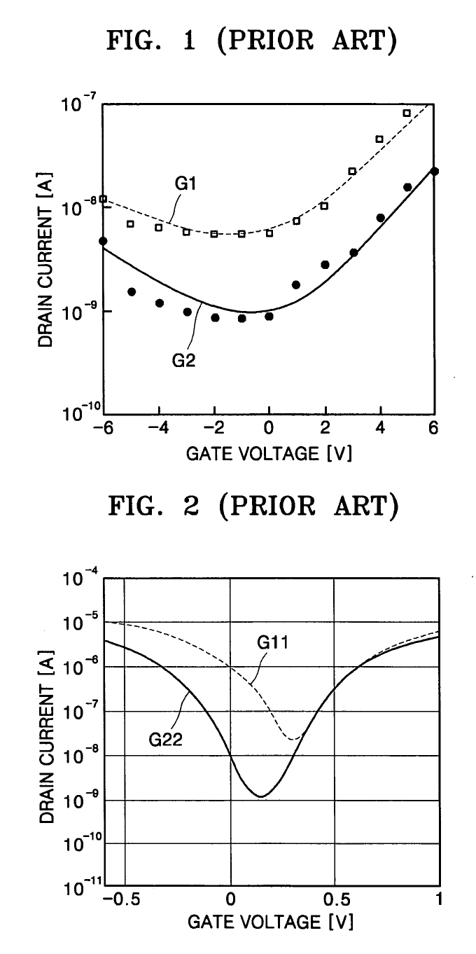

### DETAILED DESCRIPTION OF THE EXAMPLE EMBODIMENTS OF INVENTION

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

A transistor with a carbon nanotube channel and a method of manufacturing the same will now be described in detail with reference to the accompanying drawings, in which example embodiments of the invention are shown. In the drawings, the thicknesses of layers and regions are exaggerated for clarity.

First, a transistor according to example embodiments of the present invention will be described below.

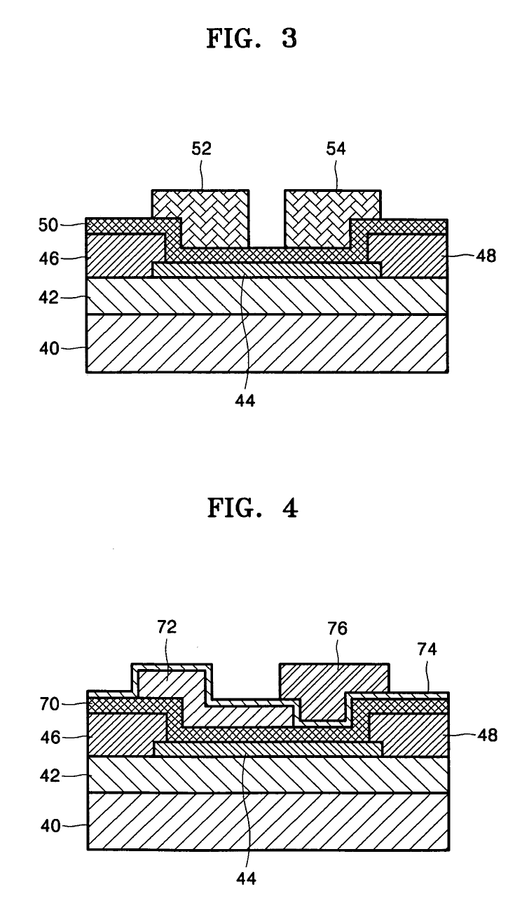

FIG. 3 is a view of a carbon nanotube transistor according to an example embodiment of the present invention.

Referring to FIG. 3, the carbon nanotube transistor (hereinafter, referred to as a first transistor) may include a substrate 40, and a first insulating layer 42 is formed on the substrate 40. In an example embodiment, the first insulating layer 42 may be formed of a material having a lower dielectric constant than that of a second insulating layer 50 (which will be described later). The first insulating layer 42 may be formed of SiO₂. Also, a first metal layer 46, a second metal layer 48, and/or a carbon nanotube channel 44 may be formed on the first insulating layer 42. The first and second metal layers 46 and 48 may act as a source and a drain, respectively. The carbon nanotube channel 44 may be formed on the first insulating layer 42 between the first metal layer 46 and the second metal layer 48 and may contact the first and second metal layers 46 and 48. The first transistor may also include a second insulating layer 50 and/or first and second gate electrodes 52 and 54. The second insulating layer 50 may act as a gate insulating layer.

In an example embodiment, the first and second gate electrodes 52 and 54 are electrically insulated from each other.

In another example embodiment, the first and second gate electrodes 52 and 54 may be disposed on the carbon nanotube channel 44 and spaced apart from each other by a desired distance.

In another example embodiment, the second insulating layer 50 may be formed of a material having a dielectric constant higher than that of the first insulating layer 42. For example, the second insulating layer 50 may be formed of ZrO₃. The second insulating layer 50 may be formed on the first and second metal layers 46 and 48 and the carbon nanotube channel 44.

When voltages are applied to the first and second gate electrodes 52 and 54 of the first transistor, a potential leakage may occur. That is, even though the first and second gate electrodes 52 and 54 are spaced apart from each other by the desired distance, an electric potential generated by the first and second gate electrodes 52 and 54 may leak to boundaries between the second insulating layer 50 and the first and second gate electrodes 52 and 54 because the second insulating layer 50 is formed of a material with a higher dielectric constant. Due to this potential leakage, the second insulating layer 50 disposed between the first gate electrode 52 and the second gate electrode 54 may be influenced by the electric potential generated by the first and second gate electrodes 52 and 54. Accordingly, this electric potential may not be concentrated in one region of the carbon nanotube channel 44, but rather may be distributed (for example, uniformly) over the entire carbon nanotube channel 44.

In this state, the voltages applied to the first and second gate electrodes 52 and 54 may be changed to control transmission coefficients of Schottky barriers between the first and second gate electrodes 52 and 54 and the carbon nanotube channel 44. In this manner, an amount of a minority carrier (e.g., a hole in the case of an N-channel transistor) flowing from the second metal layer 48 into the carbon nanotube channel 44 may be controlled.

Like reference numerals in FIGS. 3 and 4 refer to like elements.

FIG. 4 is a sectional view of a carbon nanotube transistor according to another example embodiment of the present invention.

Referring to FIG. 4, the carbon nanotube transistor (hereinafter, referred to as a second transistor) may include first and second metal layers 46 and 48 and a carbon nanotube channel 44 on a first insulating layer 42. The first insulating layer 42 may be formed of a silicon oxide layer or a nitride layer. The first and second metal layers 46 and 48 and the carbon nanotube channel 44 may be covered with a second insulating layer 70. The second insulating layer 70 may be formed of a dielectric layer (e.g., a zirconium oxide layer) having a dielectric constant higher than that of the first insulating layer 42, or may be formed of a dielectric layer (e.g., a silicon oxide layer) having a dielectric constant equal to or lower than the first insulating layer 42. A first gate electrode 72 may be formed on a desired region of the second insulating layer 70. The first gate electrode 72 may cover a portion of the carbon nanotube channel 44. The first gate electrode 72 may have the same configuration as the first gate electrode 52 in FIG. 3. A third insulating layer 74 may be formed on the second insulating layer 70 such that it covers the first gate electrode 72. The third insulating layer 74 may be a dielectric layer with a desired dielectric constant. Although the third insulating layer 74 may be made of the same dielectric layer as the second insulating layer 70, it can also be different from the second insulating layer 70. The second insulating layer 70 between the second metal layer 48 and the first gate electrode 72 may be covered with the third insulating layer 74. A second gate electrode 76 may be formed on the third insulating layer 74. The first and second gate electrode 72 and 76 may constitute a dual gate electrode. In example embodiment the second gate electrode 76 may be formed between the first gate electrode 72 and the second metal layer 48. In another example embodiment the second gate electrode 76 may extend over the first gate electrode 72, so that a portion of the second gate electrode 76 overlaps a portion of the first gate electrode 72.

In an example embodiment, the carbon nanotube channel 44 may be covered with the first and second gate electrodes 72 and 76. Consequently, the entire surface of the carbon nanotube channel 44 may face the gate electrodes 72 and 76. As a result, even when the second insulating layer 70 does not have a dielectric constant higher than the first insulating layer 42, a uniform or substantially uniform electric potential can be applied to the carbon nanotube channel 44.

In this state, the voltages applied to the first and second gate electrodes 72 and 76 may be independently controlled. In this manner, it is possible to reduce or prevent a minority carrier from flowing into the carbon nanotube channel 44 from the second metal layer 48 serving as the drain.

Below, the voltage-current characteristics of the first and second transistors will now be described.

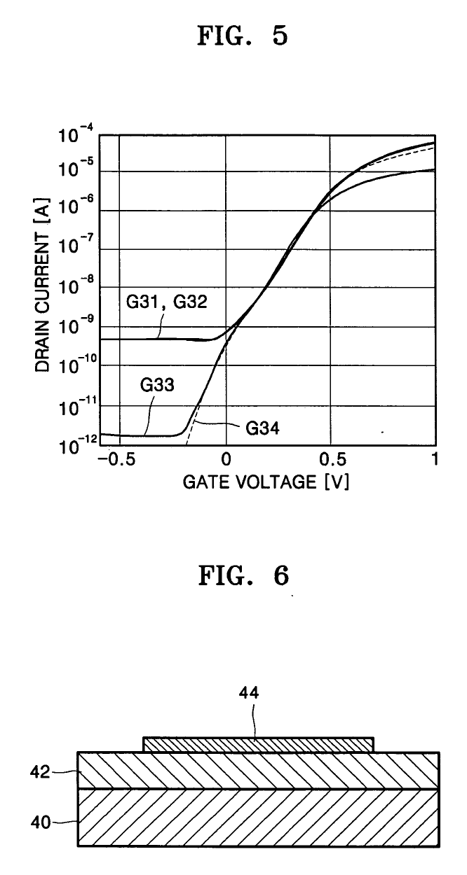

The first and second transistors were configured with N-channel transistors and their voltage-current characteristics were measured. The measurement result is illustrated in FIG. 5.

In FIG. 5, first and second graphs G31 and G32 represent the voltage-current characteristics when the voltage (V_{g}_{²}) (hereinafter, referred to as a second gate voltage) applied to the second gate electrode 54 or 76 is equal to the drain voltage (V_{d}), for example V_{d}=0.3 V and V_{d}=0.6. This case will be referred to as a first case. Third and fourth graphs G33 and G34 represent the voltage-current characteristics when the second gate voltage (V_{g}_{²}) is different from the drain voltage (V_{d}). This case will be referred to as a second case. Specifically, the third graph G33 represents the voltage-current characteristic when the second gate voltage (V_{g}_{²}) and the drain voltage (V_{d}) are 0.8 V and 0.3 V, respectively. The fourth graph represents the voltage-current characteristic when the second gate voltage (V_{g}_{²}) and the drain voltage (V_{d}) are 0.8 V and 0.6 V, respectively.

In the first case, as can be seen from the first and second graphs G31 and G32, the drain current increases as the voltage (hereinafter, referred to as a first gate voltage) applied to the first gate electrode 52 or 72 becomes higher than 0 V, and the drain current decreases as the first gate voltage becomes lower than 0 V. However, when the first gate voltage is lower than 0 V, the drain current does not decrease further, but maintains a value as the first gate voltage becomes lower than a given voltage.

In the second case, as can be seen from the third and fourth graphs G33 and G34, the drain current decreases as the first gate voltage becomes lower than 0 V. As the first gate voltage becomes lower than a voltage, the drain current does not decrease further, but maintains a given value.

In both cases, the drain current does not increase when the first gate voltage decreases. These results show that the minority carrier (e.g., the hole) is restricted or prevented from flowing into the carbon nanotube channel from the drain. Therefore, the probability that the leakage current can be generated may be reduced.

When the first and second transistors are P-channel transistors, the opposite results can be obtained. That is, in the case of P-channel transistors, when desired negative voltages are applied to the second gate electrodes 54 and 76 and the drain, the drain current increases as the first gate voltage becomes lower than 0 V. On the contrary, the current decreases as the first gate voltage becomes higher than 0 V, and the drain current maintains a value as the first gate voltage becomes higher than a given voltage. These results show that the minority carrier (e.g., an electron) is prevented from flowing into the carbon nanotube channel from the drain.

Next, methods of manufacturing the first and second transistors will be described below.

An example embodiment of a method of manufacturing the transistor of FIG. 3 will now be described with reference to FIGS. 6 through 9.

Referring to FIG. 6, a first insulating layer 42 may be formed on a substrate 40. The first insulating layer 42 may be formed of a silicon oxide layer or a dielectric layer with a lower dielectric constant. A carbon nanotube channel 44 may be formed on a desired region of the first insulating layer 42.

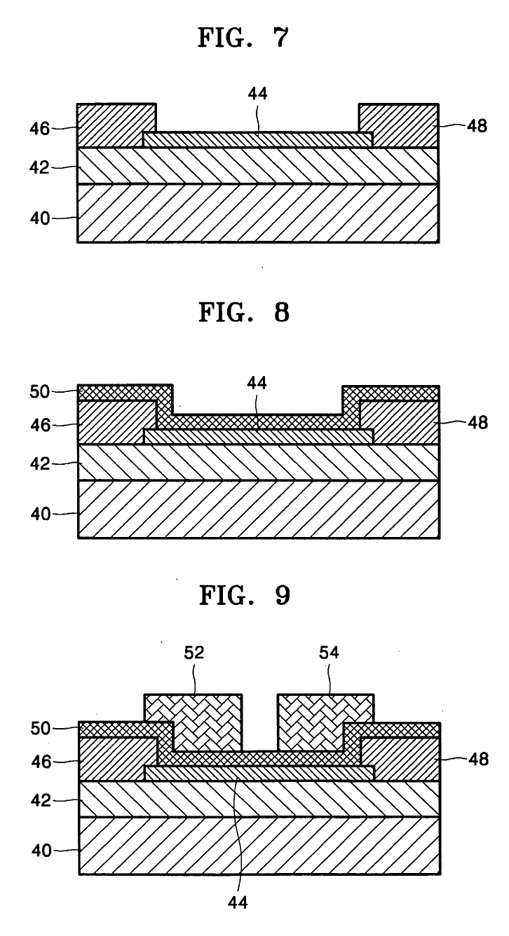

Referring to FIG. 7, first and second metal layers 46 and 48 may be formed on the first insulating layer 42. The first metal layer 46 may contact one side of the carbon nanotube channel 44 and the second metal layer 48 may contact another side of the carbon nanotube channel 44. The first metal layer 46 and the second metal layer 48 may act as a source and a drain, respectively.

Referring to FIG. 8, a second insulating layer 50 may be formed on the first and second metal layers 46 and 48 and/or the carbon nanotube channel 44. In an example embodiment, the second insulating layer 50 may be formed of a dielectric layer having a higher dielectric constant than that of the first insulating layer 42. For example, the second insulating layer 50 may be formed of a zirconium oxide layer (ZrO₃).

Referring to FIG. 9, first and second gate electrodes 52 and 54 may be formed on the second insulating layer 50 (for example, by photolithography). Both of the first and second gate electrodes 52 and 54 may be disposed above the carbon nanotube channel 44 and may be spaced apart from each other by a desired distance. Even when the first and second gate electrodes 52 and 54 are separated from each other, because the second insulating layer 50 has a higher dielectric constant, electric potential applied to the carbon nanotube channel 44 exposed between the first and second gate electrodes 52 and 54 may be equal to electric potential applied to below the first and second gate electrodes 52 and 54.

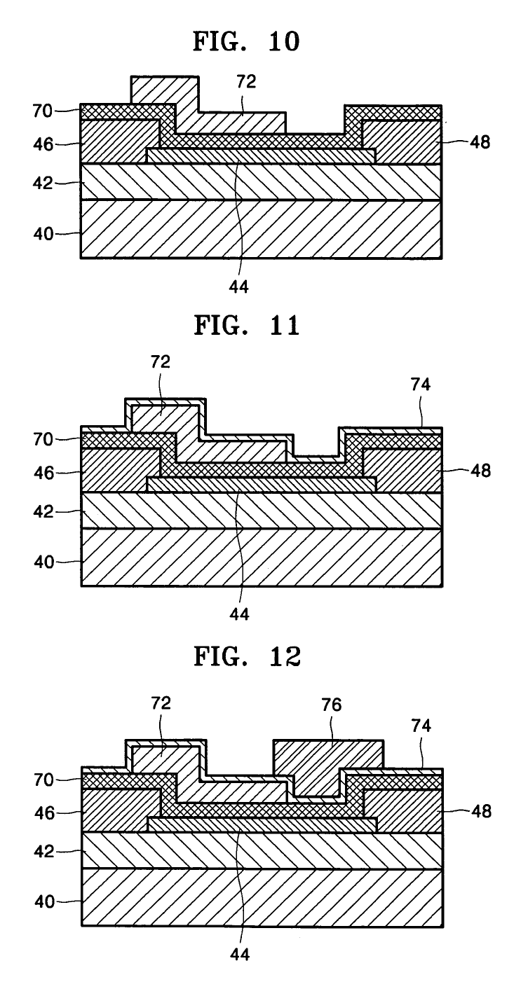

Another example embodiment of a method of manufacturing the transistor of FIG. 4 will now be described with reference to FIGS. 10 through 12.

Referring to FIG. 10, first and second metal layers 46 and 48 and a carbon nanotube channel 44 may be formed on a first insulating layer 42 in a manner described above. A second insulating layer 70 may be formed to cover the first and second metal layers 46 and 48 and the carbon nanotube channel 44. The second insulating layer 70 may be formed of a silicon oxide layer. The second insulating layer 70 may be formed of a dielectric layer having a dielectric constant equal to or higher than that of the first insulating layer 42. The second insulating layer 70 may be formed of a nitride layer. A first gate electrode 72 may be formed on the second insulating layer 70. The forming of the first gate electrode 72 may include depositing a conductive material on the second insulating layer 70, planarizing a surface of the deposited conductive layer, and/or patterning the planarized conductive layer using photolithography. Although the top surface of the first gate electrode 72 is stepped in FIG. 10, the top surface of the first gate electrode 72 may also be flat. In an example embodiment, the first gate electrode 72 is formed above the carbon nanotube channel 44 such that a portion of the carbon nanotube channel 44 is covered.

Referring to FIG. 11, a third insulating layer 74 may be formed to cover the resulting structure, for example, to cover the second insulating layer 70 and the first gate electrode 72. The third insulating layer 74 may be formed of the same material as the second insulating layer 70, or may be of other material.

Referring to FIG. 12, a second gate electrode 76 may be formed on a desired region of the third insulating layer 74. The second gate electrode 76 may be formed in a manner described above for the first gate electrode 72. In an example embodiment, the second gate electrode 76 may be formed to cover the carbon nanotube channel 44 between the first gate electrode 72 and the second metal layer 48. The second gate electrode 76 may be overlapped with a portion of the first gate electrode 72.

The first and second gates 72 and 76 may be formed in a reverse sequence. That is, the second gate electrode 76 may be formed on the second insulating layer 70 and the first gate electrode 72 may be formed on the third insulating layer 74. Also, more than two gate electrodes may be provided.

As described above, the carbon nanotube transistor according to example embodiments of the present invention may include at least two gate electrodes insulated from each other and thus have a uniform electric potential in the entire region of the channel due to different dielectric constants of the insulating layer between the substrate and the channel and the insulating layer between the channel and the gate electrode. Also, the transmission coefficients of the Schottky barriers between the carbon nanotube channel and the source and drain may be adjusted by applying independent voltages to the gate electrodes. Accordingly, the minority carrier may be prevented from flowing into the carbon nanotube channel. Consequently, it is possible to reduce or prevent the occurrence of the leakage current that is generated when both the majority carrier and the minority carrier flow into the channel. Therefore, it is possible to reduce or prevent characteristic degradation of the transistors due to the leakage current.

While the present invention has been particularly shown and described with reference to example embodiments thereof, it will be understood by those of ordinary skill in the art that various changes in form and details may be made therein without departing from the spirit and scope of the present invention as defined by the following claims.

1. A transistor comprising:
a substrate;
a first insulating layer formed on the substrate;
first and second metal layers formed on the first insulating layer and spaced apart from each other;
a nanotube channel formed on the first insulating layer, the first and second metal layers overlapping the nanotube channel;
a second insulating layer covering the nanotube channel; and
at least two gate electrodes formed on the second insulating layer, the at least two gate electrodes being electrically insulated from each other.

2. The transistor of claim 1, wherein the nanotube channel is formed on the first insulating layer between the first and second metal layers and has one side contacting the first metal layer and another side contacting the second metal layer.

3. The transistor of claim 1, wherein the second insulating layer covers the first and second metal layers and the nanotube channel.

4. The transistor of claim 1, wherein the second insulating layer is a dielectric layer having a dielectric constant higher than that of the first insulating layer.

5. The transistor of claim 1, wherein the at least two gate electrodes are spaced apart from each other.

6. The transistor of claim 1, further comprising a third insulating layer formed on the second insulating layer to cover one of the at least two gate electrodes.

7. The transistor of claim 6, wherein another of the at least two gate electrodes is disposed on the third insulating layer, the at least two gate electrodes being partially overlapped.

8. The transistor of claim 6, wherein the third insulating layer is a dielectric layer having a dielectric constant higher than that of the first insulating layer and a dielectric constant substantially equal to that of the second insulating layer.

9. The transistor of claim 1, the at least two gate electrodes including three gate electrodes formed on the second insulating layer, the three gate electrodes being insulated from each other.

10. A method of manufacturing a transistor, comprising:
forming a first insulating layer on a substrate;
forming a nanotube channel on the first insulating layer;
forming first and second metal layers on the first insulating layer spaced apart from each other, the first and second metal layers overlapping the nanotube channel;
forming a second insulating layer on the nanotube channel; and
forming at least two gate electrodes on a region of the second insulating layer, the at least two gate electrodes being electrically insulated from each other.

11. The method of claim 10, wherein forming the nanotube channel includes forming the nanotube channel between the first and second metal layers, wherein the nanotube channel has one side contacting the first metal layer and another side contacting the second metal layer.

12. The method of claim 10, wherein forming the second insulating layer includes forming the second insulating layer to cover the first and second metal layers and the nanotube channel.

13. The method of claim 10, wherein the second insulating layer is a dielectric layer having a dielectric constant higher than that of the first insulating layer.

14. The method of claim 10, wherein the at least two gate electrodes are spaced apart from each other.

15. The method of claim 10, further comprising:
forming a third insulating layer formed on the second insulating layer to cover one of the at least two gate electrodes.

16. The method of claim 15, wherein another of the at least two gate electrodes is disposed on the third insulating layer, the at least two gate electrodes being partially overlapped.

17. The method of claim 15, wherein the third insulating layer is a dielectric layer having a dielectric constant higher than that of the first insulating layer and a dielectric constant substantially equal to that of the second insulating layer.

18. The method of claim 10, the at least two gate electrodes including three gate electrodes formed on the second insulating layer, the three gate electrodes being insulated from each other.

19. A method of manufacturing a transistor including a substrate, a first insulating layer, a nanotube channel, first and second metal layers, a second insulating layer, and at least two gate electrodes, the method comprising:
forming the first insulating layer on the substrate;
forming the nanotube channel on the first insulating layer;
forming first and second metal layers on the first insulating layer spaced apart from each other, the first and second metal layers overlapping the nanotube channel;
forming the second insulating layer on the nanotube channel; and
forming the at least two gate electrodes on a region of the second insulating layer, the at least two gate electrodes being electrically insulated from each other.
